(19) United States
(12) Patent Application Publication
(10) Pub. No.: US 2025/0379114 A1
(43) Pub. Date: Dec. 11, 2025

(54) PACKAGE STRUCTURE

(71) Applicant: REALTEK SEMICONDUCTOR CORP., Hsinchu (TW)

(72) Inventors: Nai-Jen Hsuan, Hsinchu (TW); An-Ming Lee, Hsinchu (TW)

(73) Assignee: REALTEK SEMICONDUCTOR CORP., Hsinchu (TW)

(21) Appl. No.: 19/075,104

(22) Filed: Mar. 10, 2025

Related U.S. Application Data
(60) Provisional application No. 63/656,292, filed on Jun. 5, 2024.

(30) Foreign Application Priority Data
Nov. 11, 2024 (TW) 113143266

(51) Int. Cl. H01L 23/367; H01L 23/00; H01L 23/31; H01L 23/373; H01L 23/498; H01L 23/538; H01L 25/16

(52) U.S. Cl. CPC H01L 23/3675; H01L 23/3128; H01L 23/3677; H01L 23/3736; H01L 23/49811; H01L 23/49838; H01L 23/5385; H01L 24/16; H01L 25/16; H01L 2224/16225; H01L 2924/19105

(57) ABSTRACT

A package structure includes a first substrate, a die, a molding layer, a second substrate, vias, and a heat-dissipation layer. The first substrate has first lower contacts on its lower surface, and the first substrate has first upper contacts on its upper surface and electrically connected to the first lower contacts. A die is electrically connected to the first upper contacts. The molding layer laterally encapsulates the die. The second substrate on the molding layer has second upper contacts on its upper surface, and the second substrate has second lower contacts on its lower surface and electrically connected to the second upper contacts. Each of the vias is in the molding layer to electrically connect the first upper contacts and the second lower contacts. The heat-dissipation layer is on the die. The upper surface of the second substrate is higher or lower than an upper surface of the heat-dissipation layer.

### CROSS-REFERENCE TO RELATED APPLICATIONS

This application claims the benefit of U.S. provisional application Ser. No. 63/656,292, filed on Jun. 5, 2024 and claims the priority of patent application No. 113143266 filed in Taiwan, R.O.C. on Nov. 11, 2024. The entirety of the above-mentioned patent applications are hereby incorporated by references herein and made a part of the specification.

### BACKGROUND

### Technical Field

The instant disclosure relates to a package structure, particularly a package structure with a heat dissipation function.

### Related Art

Heat dissipation in semiconductor package systems has been a problem to be solved for a long time. In recent years, with the increasing complexity and demand for multifunctionality in 3D System-in-Package (SiP) applications and designs, how to effectively address heat dissipation has become a critical challenge in the art.

### SUMMARY

In view of this, a package structure is provided according to some embodiments, and the package structure comprises a first substrate, a die, a molding layer, a second substrate, a plurality of vias, and a heat-dissipation layer. The first substrate has an upper surface, a trace layer, and a lower surface. The upper surface of the first substrate has a plurality of first upper contacts. The lower surface of the first substrate has a plurality of first lower contacts. The first upper contacts are individually electrically connected to the first lower contacts through the trace layer of the first substrate. The die has an active surface and a back surface opposite to each other. The die is electrically connected to the plurality of first upper contacts of the upper surface of the first substrate through the active surface. The molding layer laterally encapsulates the die. The second substrate has an upper surface, a trace layer, and a lower surface. The second substrate is on the molding layer. The upper surface of the second substrate has a plurality of second upper contacts. The lower surface of the second substrate has a plurality of second lower contacts. The second upper contacts are individually electrically connected to the second lower contacts through the trace layer of the second substrate. Each of the vias is in the molding layer. A bottom end of each of the vias is electrically connected to one of the plurality of the first upper contacts of the first substrate, and a top end of each of the vias is electrically connected to one of the plurality of the second lower contacts of the second substrate. The heat-dissipation layer has an upper surface, and the heat-dissipation layer is on the back surface of the die. The upper surface of the second substrate is higher than or lower than the upper surface of the heat-dissipation layer.

### BRIEF DESCRIPTION OF THE DRAWINGS

The following drawings are provided solely for illustrative purposes in the detailed description to facilitate a more comprehensive understanding of some embodiments of the instant disclosure. However, these embodiments are not intended to limit the scope of the instant disclosure.

FIG. 1 illustrates a schematic structural view of a package structure according to a first embodiment;

FIG. 2 illustrates a schematic structural view of a package structure according to a second embodiment;

FIG. 3 illustrates a schematic structural view of a package structure according to a third embodiment; and

FIG. 4 illustrates a schematic structural view of a package structure according to a fourth embodiment.

### DETAILED DESCRIPTION

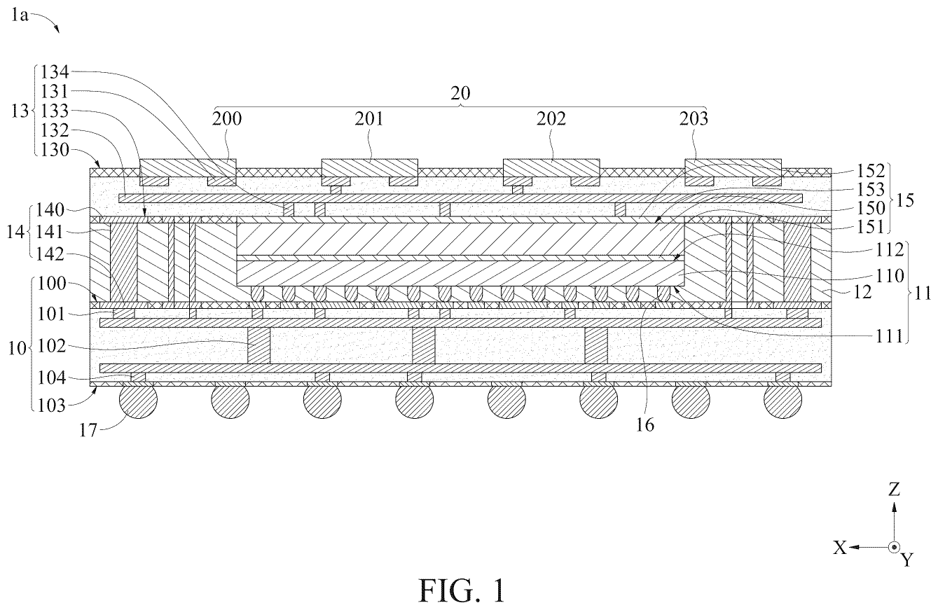

Please refer to FIG. 1. FIG. 1 illustrates a schematic structural view of a package structure 1a according to a first embodiment. In FIG. 1, a package structure 1a comprises a first substrate 10, a die 11, a molding layer 12, a second substrate 13, a plurality of vias 14, and a heat-dissipation element 15 (which comprises a heat-dissipation layer 150). The first substrate 10 has an upper surface 100, a trace layer 102, and a lower surface 103. The upper surface 100 of the first substrate 10 has a plurality of first upper contacts 101. The lower surface 103 of the first substrate 10 has a plurality of first lower contacts 104. The first upper contacts 101 are individually electrically connected to the first lower contacts 104 through the trace layer 102. The die 11 comprises a die body 110 and has an active surface 111 and a back surface 112 on two opposite sides of the die body 110. The die 11 (or the die body 110) is electrically connected to the plurality of first upper contacts 101 of the upper surface 100 of the first substrate 10 through the active surface 111 of the die 11. The molding layer 12 laterally encapsulates the die 11. The second substrate 13 has an upper surface 130, a trace layer 132, and a lower surface 133. The second substrate 13 is disposed on the molding layer 12. The upper surface 130 of the second substrate 13 has a plurality of second upper contacts 131. The lower surface 133 of the second substrate 13 has a plurality of second lower contacts 134. The second upper contacts 131 are individually electrically connected to the second lower contacts 134 through the trace layer 132. Each of the vias 14 is in the molding layer 12. A bottom end 142 of each of the vias 14 is electrically connected to one of the plurality of the first upper contacts 101 of the first substrate 10, and a top end 140 of each of the vias 14 is electrically connected to one of the plurality of the second lower contacts 134 of the second substrate 13. The heat-dissipation layer 150 has an upper surface 153, and the heat-dissipation layer 150 is disposed on the back surface 112 of the die 11. The upper surface 130 of the second substrate 13 is higher than the upper surface 153 of the heat-dissipation layer 150; for example, in FIG. 1, the second substrate 13 is disposed on the heat-dissipation layer 150 to cover the heat-dissipation layer 150 thoroughly. The term “couple/coupled/coupling” as used herein may include direct couple/coupled/coupling (e.g., physically connecting two elements directly) and indirect couple/coupled/coupling (e.g., physically connecting two elements indirectly through physical contact with another element), and the physical contact at least includes thermally conductive contact and may also include electrically conductive contact. Hence, in some embodiments, the heat generated by the die 11 and its surroundings can be conducted to a side of the heat dissipation layer 150 away from the die 11, thereby enabling the die 11 to dissipate the heat effectively.

Please still refer to FIG. 1. The first substrate 10 may be a substrate made of various material, for example, an organic or inorganic substrate. By arranging various vias (e.g., through holes, blind vias, and buried vias) between the upper surface 100 and the lower surface 103 of the first substrate 10 and utilizing solder resist based on different needs, the trace layer 102 (i.e., wiring) can be defined in a manner of non-plugged vias, partially-plugged vias, or fully-plugged vias. The non-plugged or partially-plugged vias on the upper surface 100 can serve as the first upper contacts 101, while the non-plugged or partially-plugged vias on the lower surface 103 can serve as the first lower contacts 104. That is, one of the first upper contacts 101 on the upper surface 100 can be electrically connected to one or more of the first lower contacts 104 on the lower surface 103.

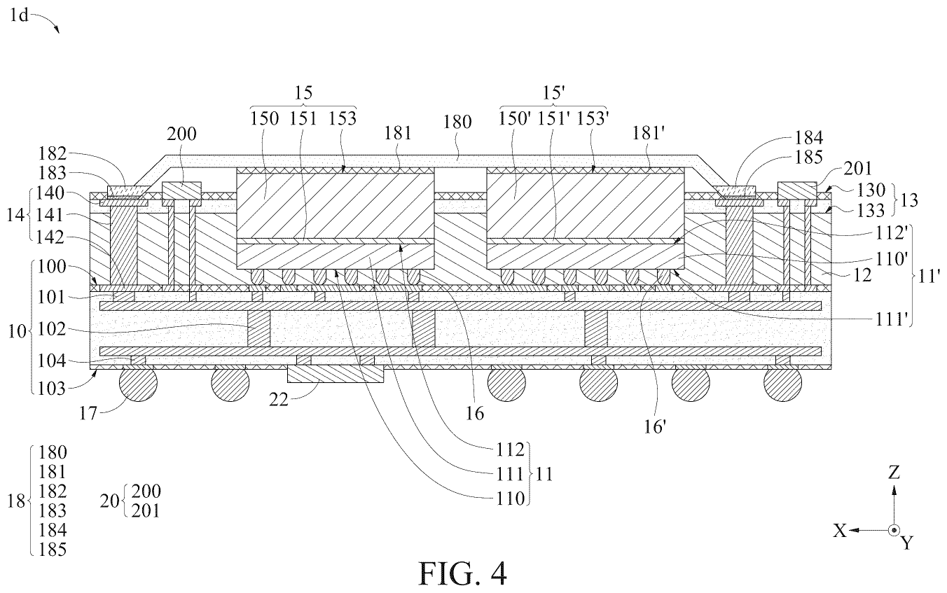

Please refer to FIG. 1 and FIG. 4. FIG. 4 illustrates a schematic structural view of a package structure 1d according to a fourth embodiment. In some embodiments, on each of the contacts 101, 104 is independently arranged with solder balls or solder pads (which can be made of various metals such as tin or its alloys); for example, as shown in FIG. 1, the first bumps 16 (which are disposed between the die 11 and the upper surface 100 and electrically connected to one or more of the first upper contacts 101) and the second bumps 17 (which are disposed on the lower surface 103 and electrically connected to one or more of the first lower contacts 104). In some embodiments, on one or more of the first lower contacts 104 can be further arranged with a passive component (e.g., a resistor, a capacitor, an inductor, a passive RF component (such as a surface wave resonator (SWR)), or any combination thereof); for example, the passive component 22 in FIG. 4 (which is disposed on the lower surface 103 and electrically connected to one or more of the first lower contacts 104).

Please still refer to FIG. 1 and FIG. 4. In some embodiments, the number of the dies 11, 11′ may be one or more, and the die 11 (or 11′) independently comprises a die body 110 (or 110′). For example, in FIG. 1, the package structure 1a comprises one die 11 and its die body 110; or for another example, in FIG. 4, the package structure d comprises a plurality of dies 11, 11′ and their die bodies 110, 110′. Unless otherwise specified, the terms “die(s)” and “die body (or die bodies)” as used herein refer to a “functional die,” to distinguish it from the “dummy die” that will be mentioned later.

Please still refer to FIG. 1. In some embodiments, the heat-dissipation layer 150 may be made of various thermally conductive materials. In some embodiments, the heat-dissipation layer 150 may be a dummy die. In some embodiments, the heat-dissipation layer 150 may be formed by graphene (also referred to as monolayer graphite or carbon monolayer) or metal. In other words, the heat-dissipation layer 150 may be any one of a dummy die, graphene, and metal; or the heat-dissipation layer 150 may be a combination of at least two of a dummy die, graphene, and metal. The dummy die refers to a die that does not possess specific functions or only has a part of functions of a functional die. The metal may be a single metal or an alloy containing multiple metals, such as gold, silver, copper, platinum, or an alloy of any combination thereof.

Please still refer to FIG. 1. In some embodiments, an area of projection surface (e.g., the XY plane) of the heat-dissipation layer 150 in a projection direction (e.g., a direction parallel to the Z direction) along a normal line (not shown) of the back surface 112 of the die 11 is greater than or equal to an area of the projection surface (e.g., the XY plane) of the die 11 in the projection direction (e.g., a direction parallel to the Z direction) so that the heat-dissipation layer 150 can be coupled to the die 11 as much as possible. Therefore, the heat generated by the die 11 can be conducted to the heat-dissipation layer 150 effectively, thereby enabling the die 11 to dissipate the heat effectively. For example, in FIG. 1, the area of projection surface of the heat-dissipation layer 150 is approximately equal to the area of projection surface of the die 11.

Please still refer to FIG. 1. In some embodiments, the heat-dissipation element 15 further comprises one or more heat-dissipation connecting portions (e.g., a first heat-dissipation connecting portion 151 and a second heat-dissipation connecting portion 152); one of the heat-dissipation connecting portions (e.g., the first heat-dissipation connecting portion 151) can be disposed between the heat-dissipation layer 150 and the die 11 to couple the heat-dissipation layer 150 to the die 11; and one of the heat-dissipation connecting portions (e.g., the second heat-dissipation connecting portion 152) can be disposed between the second substrate 13 and the heat-dissipation layer 150 to couple the second substrate 13 and the heat-dissipation layer 150. The first heat-dissipation connecting portion 151 and the second heat-dissipation connecting portion 152 may independently be various thermally conductive adhesives, such as, but not limited to, thermal interface materials (TIM). Accordingly, in some embodiments, through the arrangement of the first heat-dissipation connecting portion 151 and/or the second heat-dissipation connecting portion 152, the heat generated by the die 11 can be conducted away from the die 11, thereby enabling the die 11 to dissipate the heat effectively.

Please still refer to FIG. 1 and FIG. 4. Embodiments of the second substrate 13 as well as the upper surface 130, the second upper contacts 131, the trace layer 132, the lower surface 133, and the second lower contacts 134 of the second substrate 13 can be referred to those of the first substrate 10 as well as the upper surface 100, the first upper contacts 101, the trace layer 102, the lower surface 103, and the first lower contacts 104, which are not further described in detail herein. Furthermore, based on these embodiments, a person of ordinary skill in the art can make appropriate adjustments according to different requirements within the scope of their understanding, while still maintaining normal functionality. For example, in FIG. 4, the second substrate 13 may be understood as that at least one of the upper surface 130 and the lower surface 133 can be selectively not defined by the solder resist, or that, for example, the solder resist and the second lower contacts 134 (as shown in FIG. 1) are simply omitted from the lower surface 133 and not shown in FIG. 4. All of the above embodiments of the arrangements of the second substrate 13 are readily understood and operable by a person of ordinary skill in the art, and thus are encompassed within the scope of protection of the instant disclosure.

Please still refer to FIG. 1. In some embodiments, the lower surface 133 of the second substrate 13 is on the heat-dissipation element 15, and the second lower contacts 134 of the second substrate 13 are coupled to the heat-dissipation element 15 (e.g., the upper surface 153 of the heat-dissipation layer 150 or the upper surface of the second heat-dissipation connecting portion 152). In other words, in some embodiments, the upper surface 130 of the second substrate 13 is higher than the upper surface 153 of the heat-dissipation layer 150, and thus the heat generated by the die 11 can be conducted away from the die 11 through the heat-dissipation layer 150 and the second substrate 13, thereby enabling the die 11 to dissipate the heat effectively.

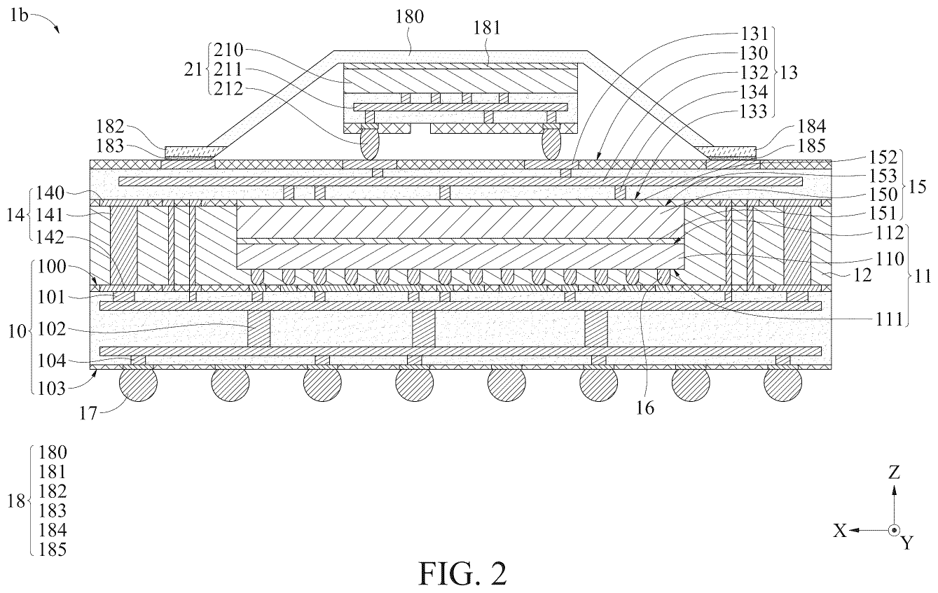

Please refer to FIG. 1 and FIG. 2. FIG. 2 illustrates a schematic structural view of a package structure 1b according to a second embodiment. In some embodiments, on one or more of the second upper contacts 131 can be further arranged with a passive component (e.g., a resistor, a capacitor, an inductor, a passive RF component (such as a surface wave resonator (SWR)), or any combination thereof) and/or an active component; for example, the passive component 20 shown in FIG. 1 (including passive sub-components 200, 201, 202, 203, which are respectively disposed on the upper surface 130 and electrically connected to one or more of the second upper contacts 131); or for another example, the active component 21 shown in FIG. 2 (which is disposed on the upper surface 130 and electrically connected to one or more of the second upper contacts 131). In some embodiments, the active components 21 comprise sequentially, from top to bottom, a die 210, a third substrate 211, and a plurality of third bumps 212; and the die 210 is electrically connected to one or more of the second upper contacts 131 through the third substrate 211 and the third bumps 212. Embodiments of the die 210, the third substrate 211, and the third bumps 212 can be referred to those of the die 11, the first substrate 10, and the second bumps 17, which are not further described in detail herein. Furthermore, based on these embodiments, a person of ordinary skill in the art can make appropriate adjustments according to different requirements within the scope of their understanding, while still maintaining normal functionality. For example, in FIG. 2, the die 210 may be understood as comprising a die or stacked dies that may or should be included in various active components 21; for example, the active component 21 may comprise stacked memory dies, allowing the active component 21 as a whole to further function as a DDR SDRAM. All of the above embodiments of the arrangements of the active component 21 are readily understood and operable by a person of ordinary skill in the art, and thus are encompassed within the scope of protection of the instant disclosure.

Please still refer to FIG. 1. In some embodiments, the molding layer 12 is disposed between the first substrate 10 and the second substrate 13 to at least laterally encapsulate the die 11. In some embodiments, the molding layer 12 further laterally encapsulates the heat-dissipation layer 150 on the die 11. The molding layer 12 may, for example, be a solid-state epoxy molding compound (EMC), such as but not limited to plastics containing epoxy resin.

Please still refer to FIG. 1. In some embodiments, each of the vias 14 comprises a via body 141 as well as a top end 140 and a bottom end 142 of the via body 141. The via body 141 may be various electrically conductive components, such as but not limited to through interposer vias (TIV), solder balls, bumps, or any combination thereof. The material of the via body 141 may, for example, be gold, silver, copper, platinum, or an alloy of any combination thereof. In some embodiments, the molding layer 12 laterally encapsulates the via bodies 141 to expose the top ends 140 and the bottom ends 142 of the via bodies 141. Therefore, each of the via bodies 141 can be electrically connected to one or more of the second lower contacts 134 of the second substrate 13 through the top ends 140 of the via bodies 141, and each of the via bodies 141 can be electrically connected to one or more of the first upper contacts 101 of the first substrate 10 through the bottom ends 142 of the via bodies 141.

Please still refer to FIG. 1. In some embodiments, the package structure 1a shown in FIG. 1 may be obtained by a manufacturing method comprising the following steps: forming a plurality of via bodies 141 on the upper surface 100 of the first substrate 10; adhering the die 11 on the upper surface 100 (e.g., through die bonding); adhering the heat-dissipation layer 150 on the back surface 112 of the die 11; molding the molding layer 12 on the upper surface 100 (e.g., through transfer molding or compression molding) to encapsulate the die 11, the heat-dissipation layer 150, and the via bodies 141; planarizing the upper surface of the molding layer 12 (e.g., through planar grinding or chemical mechanical polishing) to a level that is higher than or approximately equal to the height of the upper surface 153 of the heat-dissipation element 15; drilling the molding layer 12 (e.g., through laser drilling) to expose the desired via bodies 141; flipping to form a plurality of the second bumps 17 on the lower surface 103 of the first substrate 10; flipping again to dispose the second substrate 13 on the heat-dissipation layer 150, the molding layer 12, the via bodies 141 to couple a part of the second lower contacts 134 of the second substrate 13 to the heat-dissipation layer 150 and to couple another part of the second lower contacts 134 of the second substrate 13 to one or more of the via bodies 141; and disposing the passive component 20 (shown in FIG. 1) or the active component 21 (shown in FIG. 2) on the upper surface 130 of the second substrate 13 to have the passive component 20 or the active component 21 electrically connected to one or more of the second upper contacts 131 of the second substrate 13.

Please refer to FIG. 1 and FIG. 2. Compared with the package structure 1a shown in FIG. 1, in some embodiments, the package structure 1b shown in FIG. 2 further comprises a heat-dissipation lid 18, and the heat-dissipation lid 18 is disposed on the second substrate 13 and coupled to the heat-dissipation layer 150 through the trace layer 132 of the second substrate 13. The heat-dissipation lid 18 may be various thermally conductive materials, such as gold, silver, copper, zinc, platinum, or an alloy of any combination thereof. Hence, in some embodiments, the heat generated by the die 11 can be conducted away from the die 11 through the heat-dissipation layer 150, the second substrate 13, and the heat-dissipation lid 18, thereby enabling the die 11 to dissipate the heat more effectively.

Please still refer to FIG. 2. In some embodiments, the package structure 1b further comprises an active component 21 on the upper surface 130 of the second substrate 13, and the heat-dissipation lid 18 is disposed on the active component 21 and the second substrate 13 so that the active component 21 is disposed inside the heat-dissipation lid 18 and coupled to the heat-dissipation lid 18. Therefore, in some embodiments, the heat generated by the die 11 can be effectively conducted away from the die 11 through the heat-dissipation layer 150, the second substrate 13 as well as the heat-dissipation lid 18, and the heat generated by the active component 21 can also be effectively conducted away from the active component 21 through the heat-dissipation lid 18, thereby enabling the die 11 and the active component 21 to dissipate the heat more effectively.

Please refer to FIG. 2. In some embodiments, the heat-dissipation lid 18 comprises a main lid 180 and two side lids 182, 184. Each of the two side lids 182, 184 is coupled to the main lid 180 and disposed on the upper surface 130 of the second substrate 13, and the main lid 180 is disposed on the active component 21 so that the active component 21 is disposed inside the heat-dissipation lid 18 and at least coupled to the main lid 180. The main lid 180 and the side lids 182, 184 may independently be various thermally conductive materials, such as gold, silver, copper, zinc, platinum, or an alloy of any combination thereof; that is, the materials of the main lid 180 and the side lids 182, 184 may be the same or different.

Please still refer to FIG. 2. In some embodiments, the heat-dissipation lid 18 further comprises a main-lid connecting portion 181 and two side-lid connecting portions 183, 185. The main-lid connecting portion 181 is disposed between the main lid 180 and the active component 21 so that the active component 21 is disposed inside the heat-dissipation lid 18 and at least coupled to the main lid 180. The two side-lid connecting portions 183, 185 are respectively disposed between the second substrate 13 and the corresponding one of the side lids 182, 184 so that the side lid 182 is coupled to one or more of the second upper contacts 131 through the side-lid connecting portion 183, while the side lid 184 is coupled to one or more of the second upper contacts 131 through the side-lid connecting portion 185. The main-lid connecting portion 181 and the side-lid connecting portions 183, 185 may independently be various thermally conductive adhesives; that is, the materials of the main-lid connecting portion 181 and the side-lid connecting portions 183, 185 may be the same or different. For example, the main-lid connecting portion 181 is formed by thermal interface material (TIM), and the side-lid connecting portions 183, 185 are formed by conductive hot melt adhesives.

Please still refer to FIG. 2. Compared with the aforementioned manufacturing method of the package structure 1a, in some embodiments, the manufacturing method of the package structure 1b shown in FIG. 2 further comprises the following steps: after the step of disposing the passive component 20 (shown in FIG. 1) or the active component 21 (shown in FIG. 2) on the upper surface 130 of the second substrate 13, adhering the heat-dissipation lid 18 (e.g., the main lid 180) on the passive component 20 (shown in FIG. 1) or the active component 21 (shown in FIG. 2), and coupling the heat-dissipation lid 18 (e.g., the side lids 182, 184) to one or more of the second upper contacts 131 of the second substrate 13.

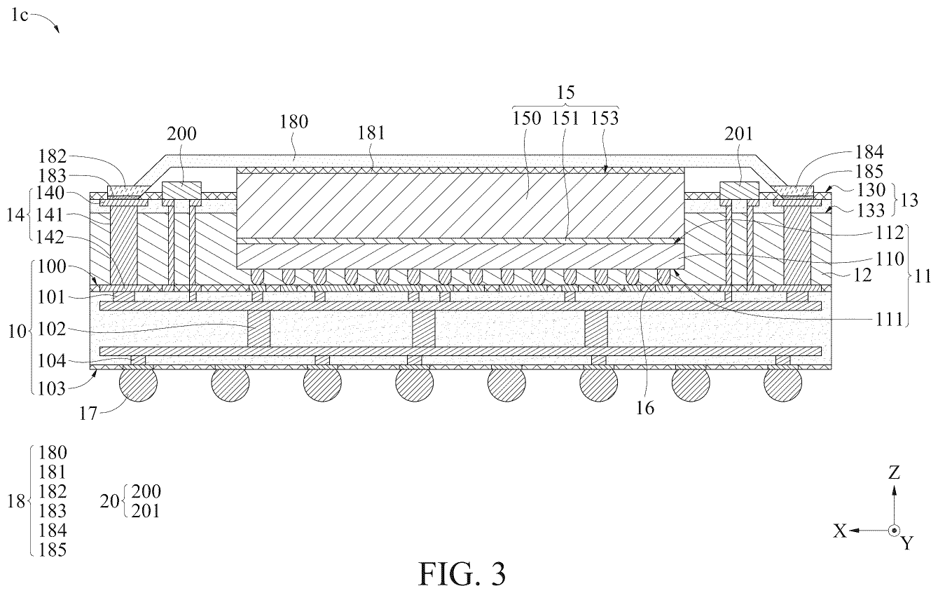

Please refer to FIG. 2 and FIG. 3. FIG. 3 illustrates a schematic structural view of a package structure 1c according to a third embodiment. Compared with the package structure 1b shown in FIG. 2, according to some embodiments, in the package structure 1c shown in FIG. 3, the upper surface 130 of the second substrate 13 is higher than the upper surface 153 of the heat-dissipation layer 150, and the heat-dissipation lid 18 is disposed on the of the upper surface 153 of the heat-dissipation layer 150 to at least couple the heat-dissipation lid 18 to the heat-dissipation layer 150. Hence, in some embodiments, the heat generated by the die 11 can be conducted away from the die 11 through the heat-dissipation layer 150 and the heat-dissipation lid 18, thereby enabling the die 11 to dissipate the heat more effectively.

Please still refer to FIG. 3. In some embodiments, the heat-dissipation lid 18 comprises a main lid 180 and two side lids 182, 184. The two side lids 182, 184 are respectively coupled to the main lid 180 and disposed on the upper surface 130 of the second substrate 13, and the main lid 180 is disposed on the heat-dissipation layer 150 so that the heat-dissipation layer 150 is disposed inside the heat-dissipation lid 18 and at least coupled to the main lid 180. Embodiments of the main lid 180 and the side lids 182, 184 can be referred to the aforementioned embodiments, which are not further described in detail herein.

Please refer to FIG. 3. In some embodiments, the heat-dissipation lid 18 further comprises a main-lid connecting portion 181 and two side-lid connecting portions 183, 185. The main-lid connecting portion 181 is disposed between the main lid 180 and the heat-dissipation layer 150 so that the heat-dissipation layer 150 is disposed inside the heat-dissipation lid 18 and at least coupled to the main lid 180. The two side-lid connecting portions 183, 185 are respectively disposed between the second substrate 13 and the corresponding one of the side lids 182, 184 so that the side lid 182 is coupled to one or more of the second upper contacts 131 through the side-lid connecting portion 183, while the side lid 184 is coupled to one or more of the second upper contacts 131 through the side-lid connecting portion 185. Embodiments of the main-lid connecting portion 181 and the side-lid connecting portions 183, 185 can be referred to the aforementioned embodiments, which are not further described in detail herein.

Please still refer to FIG. 3 and FIG. 4. In some embodiments, the passive components 20 may be disposed on the upper surface 130 of the second substrate 13 that is inside or outside the heat-dissipation lid 18 so that the passive components 20 can be electrically connected to one or more of the via bodies 141. For example, in FIG. 3, a plurality of passive sub-components 200, 201 of the passive components 20 are all disposed on upper surface 130 of the second substrate 13 that is inside the heat-dissipation lid 18. For another example, in FIG. 4, a passive sub-component 200 is disposed on upper surface 130 of the second substrate 13 that is inside the heat-dissipation lid 18, while a passive sub-component 201 is disposed on upper surface 130 of the second substrate 13 that is outside the heat-dissipation lid 18. Accordingly, in some embodiments, even though the package structure 1c (or 1d) are arranged with the heat-dissipation lid 18, the die 11 can still dissipate heat effectively with minimal impact on the arrangements of the passive components 20 or the active component 21 (shown in FIG. 2) on the upper surface 130 of the second substrate 13.

Please still refer to FIG. 3. Compared with the aforementioned manufacturing method of the package structure 1a, in some embodiments, the manufacturing method of the package structure 1c shown in FIG. 3 further comprises the following steps: in the step of planarizing the upper surface of the molding layer 12, the upper surface of the molding layer 12 is planarized to a level that is lower than the height of the upper surface 153 of the heat-dissipation layer 150; and after the step of disposing the passive components 20 (shown in FIG. 3) or the active component 21 (shown in FIG. 2) on the upper surface 130 of the second substrate 13, adhering the heat-dissipation lid 18 (e.g., the main lid 180) on the heat-dissipation layer 150, and coupling the heat-dissipation lid 18 (e.g., the side lids 182, 184) to one or more of the second upper contacts 131 of the second substrate 13.

Please refer to FIG. 3 and FIG. 4. Compared with the package structure 1c shown in FIG. 3, in some embodiments, the package structure 1d shown in FIG. 4 comprises a plurality of dies 11, 11′. The die 11 (or 11′) may have the die body 110 (or 110′) as well as the active surface 111 (or 111′) and the back surface 112 (or 112′) thereof, the first bumps 16 (or 16′), the heat-dissipation layer 150 (or 150′) as well as the upper surface 153 (or 153′) thereof, the first heat-dissipation connecting portion 151 (or 151′), and the second heat-dissipation connecting portion 152 (which can be denoted by the main-lid connecting portions 181, 181′ in FIG. 4, respectively; that is, in some embodiments, the material of the second heat-dissipation connecting portion 152 may be identical to the materials of the main-lid connecting portions 181, 181′). Hence, in some embodiments, the heat generated by the dies 11, 11′ can be conducted away from the dies 11, 11′ respectively through the heat-dissipation layers 150, 150′ and the heat-dissipation lid 18, thereby enabling the dies 11, 11′ to dissipate the heat more effectively.

Please still refer to FIG. 3 and FIG. 4. Compared with the package structure 1c shown in FIG. 3, in some embodiments, the package structure 1d shown in FIG. 4 comprises a passive component 22, and the passive component 22 is disposed on the lower surface 103 and electrically connected to one or more of the first lower contacts 104. In addition, the second bumps 17 may also be disposed on the lower surface 103 and electrically connected to one or more of the first lower contacts 104. Embodiments of the passive component 22 can be referred to the embodiments of the aforementioned passive component 22, which are not further described in detail herein.

Please still refer to FIG. 4. Compared with the aforementioned manufacturing method of the package structure 1c, in some embodiments, the manufacturing method of the package structure 1d shown in FIG. 4 can be generally referred to the aforementioned manufacturing method of the package structure 1c, which is not further described in detail herein.

To sum up, according to some embodiments, through coupling a heat-dissipation layer to the die(s), the heat generated by the die(s) can be conducted away from the die(s) through the heat-dissipation layer, thereby enabling the die(s) to dissipate the heat effectively. Furthermore, according to some embodiments, through coupling a heat-dissipation lid to the heat-dissipation layer, the heat generated by the die(s) can be further conducted away from the die(s) through the heat-dissipation lid and the heat-dissipation layer, thereby enabling the die(s) to dissipate the heat effectively. Moreover, according to some embodiments, a substrate may be disposed on the heat-dissipation layer coupled to the die(s) so as to couple the lower surface of the substrate to the heat-dissipation layer; an active component may be disposed on the substrate to couple the active component to the heat-dissipation layer through the substrate; therefore, the heat generated by the die(s) can be conducted away from the die(s) through the heat-dissipation layer, the heat-dissipation lid, and the substrate, and the heat generated by the active component can also be conducted away from the active component through the heat-dissipation lid, thereby enabling the die(s) to dissipate the heat of both the die(s) and the active component effectively.

Although the instant disclosure is disclosed in the foregoing embodiments as above, it is not intended to limit the instant disclosure. Any person who is familiar with the relevant art can make some changes and modifications without departing from the spirit and scope of the instant disclosure. Therefore, the scope of the instant disclosure shall be subject to the definition of the scope of patent application attached to the specification.

What is claimed is:

1. A package structure, comprising:
a first substrate having an upper surface, a trace layer, and a lower surface, wherein the upper surface has a plurality of first upper contacts, the lower surface has a plurality of first lower contacts, and the plurality of first upper contacts are individually electrically connected to the plurality of first lower contacts through the trace layer of the first substrate;
a die having an active surface and a back surface opposite to each other, wherein the die is electrically connected to the plurality of first upper contacts of the upper surface of the first substrate through the active surface;
a molding layer laterally encapsulating the die;
a second substrate having an upper surface, a trace layer, and a lower surface, wherein the second substrate is on the molding layer, the upper surface of the second substrate has a plurality of second upper contacts, the lower surface of the second substrate has a plurality of second lower contacts, and the plurality of second upper contacts are individually electrically connected to the plurality of second lower contacts through the trace layer of the second substrate;
a plurality of vias in the molding layer, wherein a bottom end of each of the vias is electrically connected to one of the plurality of the first upper contacts of the first substrate, and a top end of each of the vias is electrically connected to one of the plurality of the second lower contacts of the second substrate; and
a heat-dissipation layer having an upper surface, wherein the heat-dissipation layer is on the back surface of the die;
wherein the upper surface of the second substrate is higher than the upper surface of the heat-dissipation layer.

2. The package structure according to claim 1, wherein an area of projection surface of the heat-dissipation layer in a projection direction along a normal line of the back surface of the die is greater than or equal to an area of the projection surface of the die in the projection direction.

3. The package structure according to claim 1, wherein the heat-dissipation layer is selected from at least one of a dummy die, graphene, and metal.

4. The package structure according to claim 1, further comprising a plurality of first bumps, wherein the plurality of the first bumps are between the die and the upper surface of the first substrate, and each of the first bumps is electrically connected to one of the plurality of the first upper contacts of the first substrate.

5. The package structure according to claim 1, further comprising a plurality of second bumps, wherein the plurality of the second bumps are on the lower surface of the first substrate, and each of the second bumps is electrically connected to one of the plurality of the first lower contacts of the first substrate.

6. The package structure according to claim 1, further comprising a passive component, wherein the passive component is on the lower surface of the first substrate, and the passive component is electrically connected to one of the plurality of the first lower contacts of the first substrate.

7. The package structure according to claim 1, further comprising a passive component, wherein the passive component is on the upper surface of the second substrate, and the passive component is electrically connected to one of the plurality of the second upper contacts of the second substrate.

8. The package structure according to claim 1, further comprising:
a heat-dissipation lid on the upper surface of the second substrate;
an active component on the upper surface of the second substrate and inside the heat-dissipation lid, wherein the active component is electrically connected to one of the plurality of the second upper contacts of the second substrate, and the heat-dissipation lid is coupled to the active component.

9. The package structure according to claim 1, further comprising a heat-dissipation connecting portion between the upper surface of the second substrate and the heat-dissipation layer.

10. A package structure, comprising:
a first substrate having an upper surface, a trace layer, and a lower surface, wherein the upper surface has a plurality of first upper contacts, the lower surface has a plurality of first lower contacts, and the plurality of first upper contacts are individually electrically connected to the plurality of first lower contacts through the trace layer of the first substrate;
a die having an active surface and a back surface opposite to each other, wherein the die is electrically connected to the plurality of first upper contacts of the upper surface of the first substrate through the active surface;
a molding layer laterally encapsulating the die;
a second substrate having an upper surface, wherein the second substrate is on the molding layer;
a plurality of vias in the molding layer, wherein a bottom end of each of the vias is electrically connected to one of the plurality of the first upper contacts of the first substrate; and
a heat-dissipation layer having an upper surface, wherein the heat-dissipation layer is on the back surface of the die;
wherein the upper surface of the second substrate is lower than the upper surface of the heat-dissipation layer.

11. The package structure according to claim 10, wherein an area of projection surface of the heat-dissipation layer in a projection direction along a normal line of the back surface of the die is greater than or equal to an area of the projection surface of the die in the projection direction.

12. The package structure according to claim 10, wherein the heat-dissipation layer is selected from at least one of a dummy die, graphene, and metal.

13. The package structure according to claim 10, further comprising a plurality of first bumps, wherein the plurality of the first bumps are between the die and the upper surface of the first substrate, and each of the first bumps is electrically connected to one of the plurality of the first upper contacts of the first substrate.

14. The package structure according to claim 10, further comprising a plurality of second bumps, wherein the plurality of the second bumps are on the lower surface of the first substrate, and each of the second bumps is electrically connected to one of the plurality of the first lower contacts of the first substrate.

15. The package structure according to claim 10, further comprising a passive component, wherein the passive component is on the lower surface of the first substrate, and the passive component is electrically connected to one of the plurality of the first lower contacts of the first substrate.

16. The package structure according to claim 10, further comprising a passive component, wherein the passive component is on the upper surface of the second substrate, and the passive component is electrically connected to a top end of at least one of the plurality of the vias.

17. The package structure according to claim 10, further comprising a heat-dissipation lid, wherein the heat-dissipation lid is on the upper surface of the second substrate and coupled to the heat-dissipation layer.

18. The package structure according to claim 17, wherein the heat-dissipation lid comprises:
a main lid on the heat-dissipation layer; and
two side lids coupled to the main lid and on the upper surface of the second substrate.

19. The package structure according to claim 18, wherein the heat-dissipation lid further comprises:
a main-lid connecting portion between the main lid and the heat-dissipation layer; and
two side-lid connecting portion between the upper surface of the second substrate and the two side lids.

20. The package structure according to claim 19, further comprising a passive component, wherein the passive component is on the upper surface of the second substrate, the passive component is inside or outside the heat-dissipation lid, and the passive component is electrically connected to a top end of at least one of the plurality of the vias.
